(19) United States
(12) Patent Application Publication
(10) Pub. No.: US 2013/0249064 A1
(43) Pub. Date: Sep. 26, 2013

(54) STACKED PACKAGE AND METHOD OF MANUFACTURING STACKED PACKAGE

(71) Applicants: Hiroaki YAMAZAKI, Kanagawa (JP); Yoshiaki Sugizaki, Kanagawa (JP); Kazuyuki Higashi, Kanagawa (JP); Yoshiaki Shimooka, Kanagawa (JP)

(72) Inventors: Hiroaki YAMAZAKI, Kanagawa (JP); Yoshiaki Sugizaki, Kanagawa (JP); Kazuyuki Higashi, Kanagawa (JP); Yoshiaki Shimooka, Kanagawa (JP)

(73) Assignee: Kabushiki Kaisha Toshiba, Tokyo (JP)

(21) Appl. No.: 13/613,434

(22) Filed: Sep. 13, 2012

(30) Foreign Application Priority Data
Mar. 21, 2012 (JP) 2012-063460

(51) Int. Cl. H01L 23/48; H01L 21/50; H01L 23/552

(52) U.S. Cl. CPC H01L 23/48; H01L 23/552; H01L 21/50
USPC 257/660; 257/773; 438/113

(57) ABSTRACT

According to an embodiment, there are provided a semiconductor chip having a semiconductor element formed thereon, a pad electrode formed on the semiconductor chip and connected to the semiconductor element, a resin layer formed on the semiconductor chip, a foundation insulating layer on which an electronic element and an internal electrode are formed, a hollow body formed on the foundation insulating layer to cover the electronic element and having a top surface side embedded in the resin layer, an opening portion formed on the foundation insulating layer and configured to expose a back surface of the internal electrode, and a conductive layer configured to connect the pad electrode and the internal electrode through the opening portion.

### CROSS-REFERENCE TO RELATED APPLICATIONS

This application is based upon and claims the benefit of priority from Japanese Patent Application No. 2012-63460, filed on Mar. 21, 2012; the entire contents of which are incorporated herein by reference.

### FIELD

Embodiments described herein relate generally to a stacked package and a method of manufacturing the stacked package.

### BACKGROUND

In the case in which mechanical element components of an MEMS or the like are integrated on an identical substrate, it is possible to easily implement an integration with an electronic circuit while exactly applying a semiconductor manufacturing process. For this reason, a silicon substrate is often used. A cavity structure is formed on the silicon substrate to create a movable portion on the silicon substrate, and an operation is carried out by utilizing a vibration, a flexure or the like of the movable portion so that a characteristic of the MEMS (Micro Electro Mechanical System) is obtained.

Moreover, there is a method of face-down mounting an MEMS chip on an IC chip in order to shorten a wiring path between the MEMS chip and the IC chip in the case in which the MEMS chip is connected to the IC chip.

### BRIEF DESCRIPTION OF THE DRAWINGS

FIG. 1 is a sectional view illustrating a schematic structure of a stacked package according to a first embodiment;

FIG. 2 is a sectional view illustrating a method of manufacturing a stacked package according to a second embodiment;

FIGS. 3A and 3B are sectional views illustrating the method of manufacturing a stacked package according to the second embodiment;

FIGS. 4A and 4B are sectional views illustrating the method of manufacturing a stacked package according to the second embodiment;

FIGS. 5A and 5B are sectional views illustrating the method of manufacturing a stacked package according to the second embodiment;

FIGS. 6A and 6B are sectional views illustrating the method of manufacturing a stacked package according to the second embodiment;

FIGS. 7A and 7B are sectional views illustrating the method of manufacturing a stacked package according to the second embodiment;

FIGS. 8A and 8B are sectional views illustrating the method of manufacturing a stacked package according to the second embodiment;

FIGS. 9A and 9B are sectional views illustrating the method of manufacturing a stacked package according to the second embodiment;

FIGS. 10A and 10B are sectional views illustrating the method of manufacturing a stacked package according to the second embodiment;

FIGS. 11A and 11B are sectional views illustrating the method of manufacturing a stacked package according to the second embodiment;

FIGS. 12A and 12B are sectional views illustrating the method of manufacturing a stacked package according to the second embodiment;

FIG. 13 is a sectional view illustrating the method of manufacturing a stacked package according to the second embodiment;

FIG. 14 is a sectional view illustrating a schematic structure of a stacked package according to a third embodiment;

FIG. 15 is a sectional view illustrating a schematic structure of a stacked package according to a fourth embodiment; and

FIGS. 16A and 16B are sectional views illustrating a method of manufacturing a stacked package according to a fifth embodiment.

### DETAILED DESCRIPTION

In general, according to one embodiment, there are provided a semiconductor chip, a pad electrode, a resin layer, a hollow body, an opening portion and a conductive layer. The semiconductor chip has a semiconductor element formed thereon. The pad electrode is formed on the semiconductor chip and is connected to the semiconductor element. The resin layer is formed on the semiconductor chip. A foundation insulating layer has an electronic element and an internal electrode formed thereon. The hollow body is formed on the foundation insulating layer to cover the electronic element and has a top surface side embedded in the resin layer. The opening portion is formed on the foundation insulating layer to expose a back surface of the internal electrode. The conductive layer connects the pad electrode and the internal electrode through the opening portion.

The stacked package and the method of manufacturing the stacked package according to the embodiments will be described below with reference to the drawings. The present invention is not restricted by these embodiments.

### First Embodiment

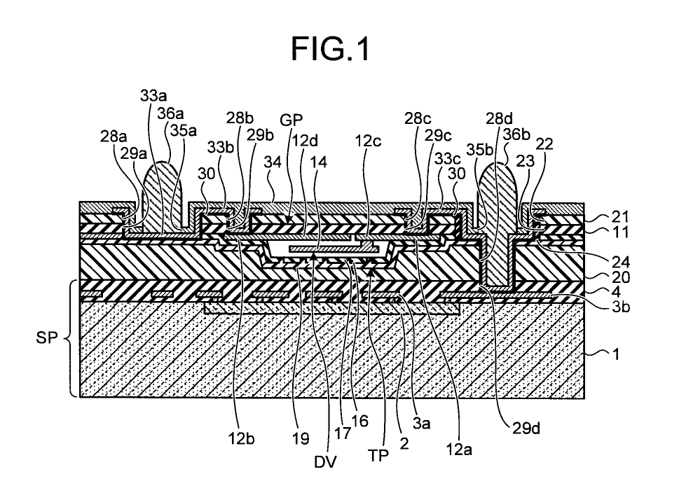

FIG. 1 is a sectional view illustrating a schematic structure of a stacked package according to a first embodiment.

In FIG. 1, the stacked package is provided with a semiconductor chip SP having a semiconductor element 2 formed therein and a hollow chip GP having an electronic element DV formed in an inner part. A resin layer 20 is formed on the semiconductor chip SP and the hollow chip GP is face-down mounted to be embedded in the resin layer 20.

More specifically, a semiconductor substrate 1 is provided in the semiconductor chip SP, and the semiconductor element 2 is formed in the semiconductor substrate 1. A material of the semiconductor substrate 1 can be selected from Si, Ge, SiGe, SiC, SiSn, PbS, GaAs, InP, GaP, GaN, ZnSe, GaInAsP and the like, for example. Moreover, the semiconductor element 2 may be an active element such as a transistor or a passive element such as a resistor or a capacitor.

A wiring 3a and a pad electrode 3b which are connected to the semiconductor element 2 are formed on the semiconductor substrate 1, and a protective film 4 is formed on the wiring 3a and the pad electrode 3b. As materials of the wiring 3a and the pad electrode 3b, for example, it is possible to use a metal such as Al or Cu. As a material of the protective film 4, for example, it is possible to use an inorganic insulating film such as a silicon oxide film or a silicon nitride film.

The resin layer 20 is formed on the protective film 4. As the resin layer 20, for example, it is possible to use an epoxy resin, a polyimide resin, an acrylic resin, a silicone resin or a phenolic resin. The resin layer 20 may be a coated film or a sheet film.

Moreover, internal electrodes 12a and 12b and lower wirings 12c and 12d are formed on a foundation insulating layer 11, and furthermore, an upper wiring 14 is formed on the lower wiring 12d. An air gap is formed between the upper wiring 14 and the lower wiring 12d in such a manner that the upper wiring 14 can be flexed in a vertical direction, and an MEMS element can be thus constituted as the electronic element DV. The MEMS element can use the upper wiring 14 as a movable electrode and can use the lower wiring 12d as a driving electrode for driving the movable electrode. As a material of the foundation insulating layer 11, moreover, it is possible to use an inorganic insulating film such as a silicon oxide film or a silicon nitride film, for example. As materials of the internal electrodes 12a and 12b, the lower wirings 12c and 12d, and the upper wiring 14, for example, it is possible to use a metal such as Al or Cu. In the case in which the MEMS element is formed as an electronic element on the foundation insulating layer 11, furthermore, a driver for driving the MEMS element can be formed on the semiconductor element 2.

In addition, a cap layer 16 constituting an outer shell of the hollow body for covering the lower wirings 12c and 12d and the upper wiring 14 is formed on the foundation insulating layer 11, and an opening portion 17 for communicating with an inner part of the hollow body is formed on the cap layer 16. A sealing layer 19 for closing the opening portion 17 is formed on the cap layer 16. As a material of the cap layer 16, for example, it is possible to use an inorganic insulating film such as a silicon oxide film or a silicon nitride film. As a material of the sealing layer 19, for example, it is possible to use a resin such as polyimide.

The foundation insulating layer 11 is disposed on the resin layer 20 in such a manner that a top surface TP side of the hollow body for covering the lower wirings 12c and 12d and the upper wiring 14 is embedded in the resin layer 20. It is preferable that the hollow body should be embedded in the resin layer 20 to keep away from the pad electrode 3b. Moreover, the foundation insulating layer 11 can be disposed on the resin layer 20 with a side end thereof provided along an outer periphery of the semiconductor chip SP. For example, the side end of the foundation insulating layer 11 may be constituted to be aligned with that of the semiconductor chip SP. In addition, the side end of the resin layer 20 may be constituted to be aligned with that of the semiconductor chip SP. The side end of the foundation insulating layer 11 does not need to be always aligned with that of the semiconductor chip SP but the foundation insulating layer 11 may be removed over a scribe line.

The side end of the foundation insulating layer 11 is constituted to be aligned with that of the semiconductor chip SP so that the hollow chips GP integrated like a wafer through the foundation insulating layer 11 and the semiconductor chips SP integrated like a wafer through the semiconductor substrate 1 can be stuck together in a lump through the resin layer 20. For this reason, the hollow chips GP do not need to be mounted on the semiconductor chips SP one by one and an aligning step and a mounting step do not need to be carried out every hollow chip GP. Consequently, it is possible to decrease the number of the steps.

A reinforced layer 21 is formed on a back side of the foundation insulating layer 11 and a solder resist layer 34 is formed on the reinforced layer 21. As a material of the reinforced layer 21, for example, it is possible to use a resin such as photosensitive polyimide.

An opening portion 29a for exposing the sealing layer 19 is formed on the foundation insulating layer 11 and the cap layer 16, and an opening portion 28a for exposing the sealing layer 19 is formed on the reinforced layer 21 through the opening portion 29a. Moreover, an opening portion 29b for exposing the internal electrode 12b is formed on the foundation insulating layer 11, and an opening portion 28b for exposing the internal electrode 12b through the opening portion 29b is formed on the reinforced layer 21. Furthermore, an opening portion 29c for exposing the internal electrode 12a is formed on the foundation insulating layer 11, and an opening portion 28c for exposing the internal electrode 12a through the opening portion 29c is formed on the reinforced layer 21. In addition, an opening portion 29d for exposing the pad electrode 3b is formed on the protective film 4, an opening portion 28d for exposing the pad electrode 3b through the opening portion 29d is formed on the resin layer 20 and the sealing layer 19, an opening portion 23 for exposing the pad electrode 3b through the opening portions 28d and 29d is formed on the foundation insulating layer 11, and an opening portion 22 for exposing the pad electrode 3b through the opening portions 23, 28d and 29d is formed on the reinforced layer 21.

A land electrode 33a is formed on the back side of the sealing layer 19 through a seed metal layer 30. Moreover, a conductive layer 33b is formed on the reinforced layer 21 through the seed metal layer 30. The conductive layer 33b is connected to the land electrode 33a through the opening portions 28a and 29a and is connected to the internal electrode 12b through the opening portions 28b and 29b. Furthermore, a conductive layer 33c is formed on the reinforced layer 21 through the sheet metal layer 30. The conductive layer 33c is connected to the internal electrode 12a through the opening portions 28c and 29c and is connected to the pad electrode 3b through the opening portions 22, 23 and 28d.

It is preferable that a conductor and a semiconductor, for example, the seed metal layer 30, the conductive layers 33b and 33c and the like should not be disposed on the back side of the hollow body constituted by the cap layer 16.

The solder resist layer 34 is formed on the land electrode 33a and the conductive layers 33b and 33c. An opening portion 35a for exposing the land electrode 33a and an opening portion 35b for exposing the conductive layer 33c provided on the pad electrode 3b are formed on the solder resist layer 34.

A projecting electrode 36a is formed on the land electrode 33a through the opening portion 35a, and a projecting electrode 36b is formed on the conductive layer 33c provided on the pad electrode 3b through the opening portion 35b. As the projecting electrodes 36a and 36b, for example, it is also possible to use a solder ball or a metal bump such as Au or Ni.

A conductor or a semiconductor is prevented from being disposed on the back side of the hollow body constituted by the cap layer 16. Consequently, it is possible to reduce a parasitic capacitance together with the electronic element DV. Also in the case in which the electronic element DV is operated in a radio frequency band, it is possible to suppress a deterioration in the characteristic of the electronic element DV.

By embedding the top surface TP of the hollow body constituted by the cap layer 16 in the resin layer 20, moreover, it is possible to provide an air gap between the electronic element DV and the semiconductor element 2. Consequently, it is possible to reduce a parasitic capacitance between the electronic element DV and the semiconductor element 2 and to enhance a Q value of the electronic element DV, and furthermore, to lessen the influence of a noise received from the semiconductor element 2.

By providing the air gap between the electronic element DV and the semiconductor element 2, furthermore, it is possible to dispose the electronic element DV on the semiconductor element 2, thereby reducing a chip size while suppressing the influence of the noise received from the semiconductor element 2.

In addition, by forming the opening portion 29a for exposing the sealing layer 19 on the foundation insulating layer 11 and the cap layer 16 and forming the land electrode 33a on the sealing layer 19 through the opening portion 29a, it is possible to prevent the land electrode 33a from being disposed on the foundation insulating layer 11 and the cap layer 16. For this reason, also in the case in which the foundation insulating layer 11 and the cap layer 16 are constituted by an inorganic insulating layer or the case in which a stress is applied to the land electrode 33a in a probe inspection or mounting, it is possible to prevent the foundation insulating layer 11 and the cap layer 16 from being cracked, thereby enhancing a reliability.

Moreover, the foundation insulating layer 11 and the cap layer 16 are constituted by an inorganic insulating layer. Consequently, it is possible to enhance a moisture resistance of the foundation insulating layer 11 and the cap layer 16. Therefore, it is possible to prevent the electronic element DV from being exposed to a moisture or the like through the resin layer 20 or the like. Thus, it is possible to enhance a resistance to a corrosion of the electronic element DV or the like.

### Second Embodiment

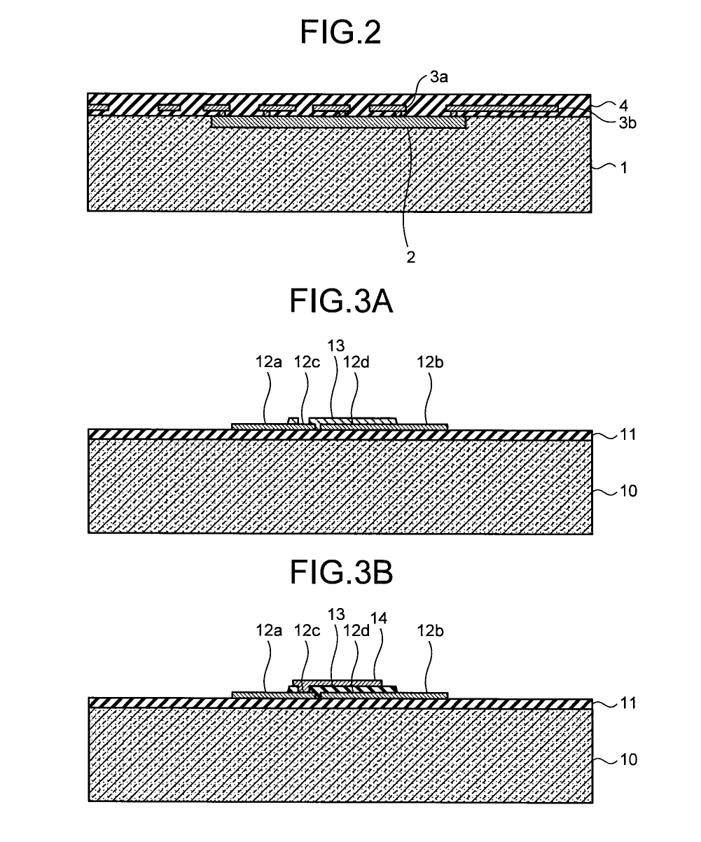

FIGS. 2 to 13 are sectional views illustrating a method of manufacturing a stacked package according to a second embodiment.

In FIG. 2, a semiconductor element 2 is formed on a semiconductor substrate 1. A wiring 3a and a pad electrode 3b which are connected to the semiconductor element 2 are formed on a semiconductor substrate 1, and a protective film 4 is formed on the wiring 3a and the pad electrode 3b.

On the other hand, as illustrated in FIG. 3A, a foundation insulating layer 11 is formed on a semiconductor substrate 10 by a method such as CVD. As a material of the semiconductor substrate 10, for example, it is possible to use Si.

Next, a conductor film is formed on the foundation insulating layer 11 by a method such as sputtering or vapor deposition and is then subjected to patterning by a photolithography technique and an etching technique so that internal electrodes 12a and 12b and lower wirings 12c and 12d are formed on the foundation insulating layer 11.

Subsequently, a sacrificial film 13 such as photosensitive polyimide or SOG is formed on the internal electrodes 12a and 12b and the lower wirings 12c and 12d by using a method such as a coating method. Then, the sacrificial film 13 is subjected to the patterning by using the photolithography technique and the etching technique to expose a part of the lower wiring 12c in such a manner that the sacrificial film 13 is left in a part of the lower wiring 12d.

As illustrated in FIG. 3B, then, a conductor film is formed on the sacrificial film 13 by a method such as sputtering or vapor deposition and is thereafter subjected to the patterning by the photolithography technique and the etching technique so that an upper wiring 14 connected to the lower wiring 12c is formed on the sacrificial film 13.

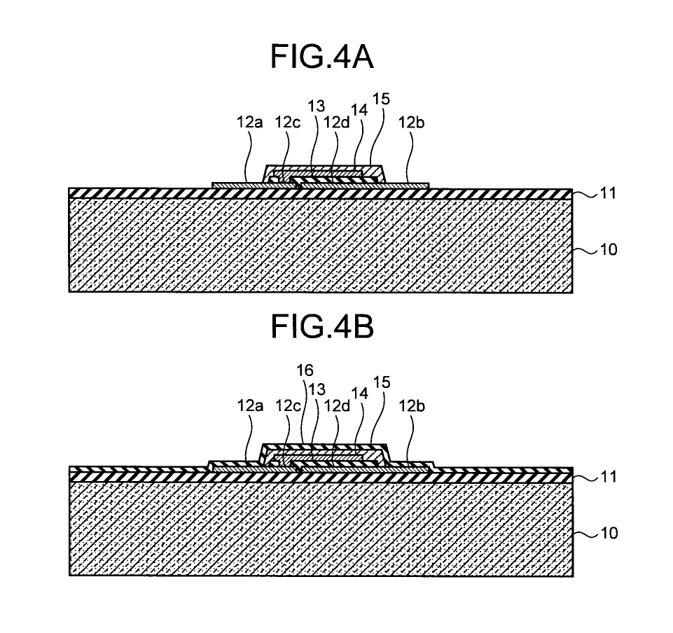

As illustrated in FIG. 4A, next, a sacrificial film 15 such as photosensitive polyimide or SOG is formed on the internal electrodes 12a and 12b, the lower wirings 12c and 12d and the upper wiring 14 by using a method such as a coating method. Subsequently, the sacrificial film 15 is subjected to the patterning by using the photolithography technique and the etching technique to expose surfaces of the internal electrodes 12a and 12b with the whole upper wiring 14 covered.

As illustrated in FIG. 4B, then, a cap layer 16 is formed on the foundation insulating layer 11, the internal electrodes 12a and 12b and the sacrificial film 15 by a method such as CVD.

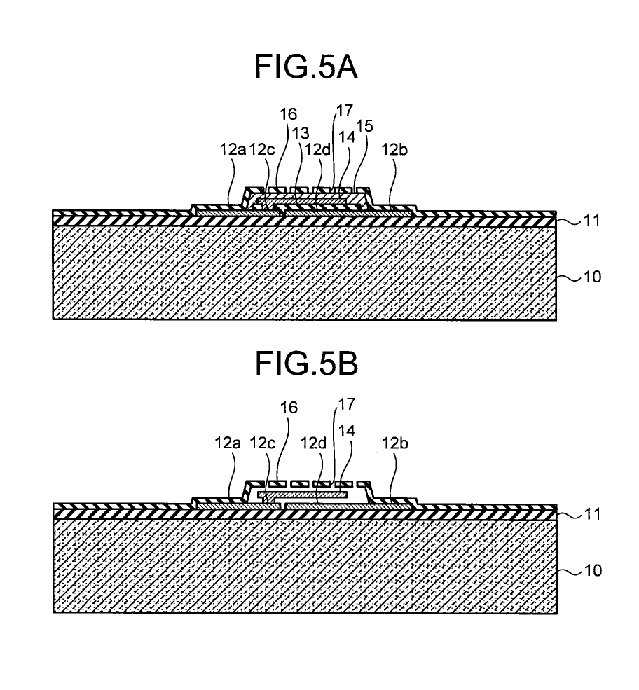

As illustrated in FIG. 5A, thereafter, the cap layer 16 is subjected to the patterning by using the photolithography technique and the etching technique to form an opening portion 17 for exposing a part of the sacrificial film 15.

As illustrated in FIG. 5B, next, the sacrificial films 13 and 15 are subjected to etching through the opening portion 17 so that the sacrificial films 13 and 15 in the cap layer 16 are removed and a hollow body disposed on the foundation insulating film 11 is constituted by the cap layer 16. As a method of removing the sacrificial films 13 and 15 in the cap layer 16, for example, it is possible to use oxygen ashing or the like.

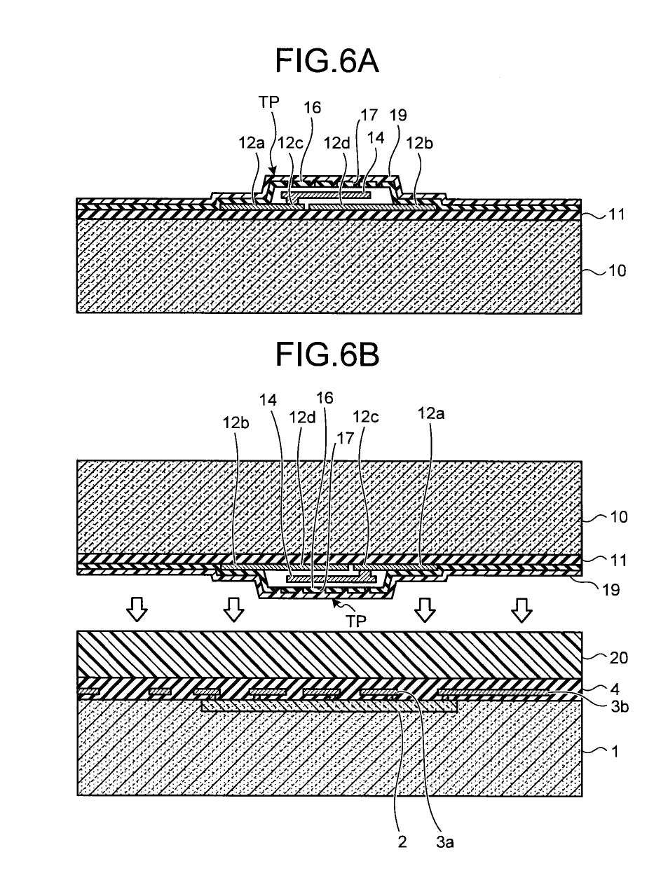

As illustrated in FIG. 6A, subsequently, a sealing layer 19 for closing the opening portion 17 is formed on the cap layer 16 by using a method such as spin coating. By properly setting a surface tension of the sealing layer 19, it is possible to prevent the sealing layer 19 from sticking to the lower wirings 12c and 12d and the upper wiring 14 through the opening portion 17.

As illustrated in FIG. 6B, then, a resin layer 20 is formed on the protective film 4 by a method such as the coating method. As the method of forming the resin layer 20 on the protective film 4, a resin sheet may be stuck to the protective film 4. Thereafter, the semiconductor substrate 10 is held in such a manner that a top surface TP of the hollow body constituted by the cap layer 16 is opposed to the resin layer 20.

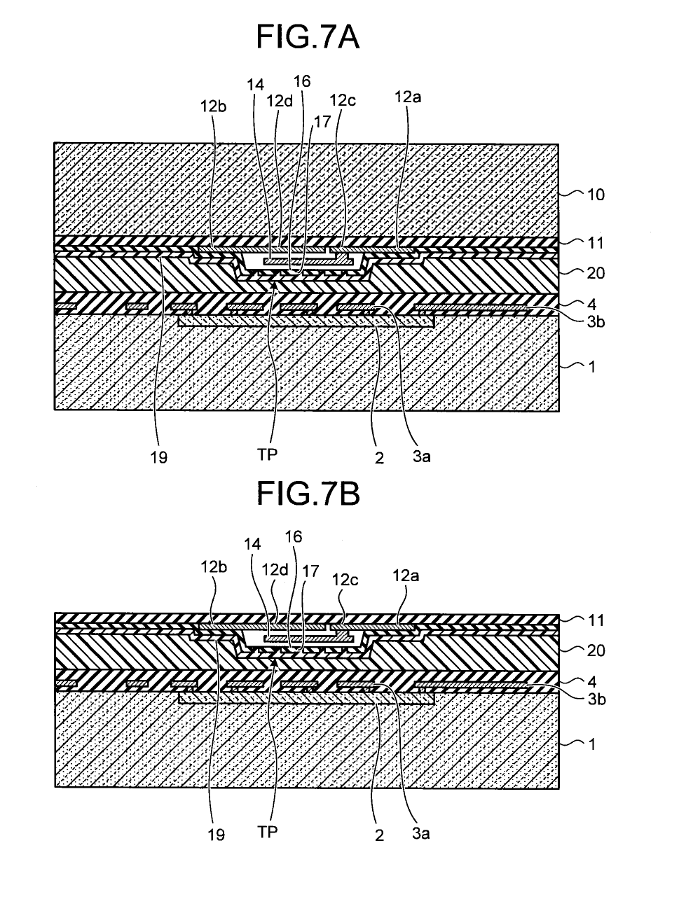

As illustrated in FIG. 7A, next, the hollow body constituted by the cap layer 16 is pushed against the resin layer 20 and is thus embedded in the resin layer 20 to cure the resin layer 20.

In the case in which the hollow body constituted by the cap layer 16 is embedded in the resin layer 20, simple substances of a semiconductor chip SP and a hollow chip GP may be bonded to each other or a semiconductor wafer having the semiconductor chips SP integrated through the semiconductor substrate 1 and a semiconductor wafer having the hollow chips GP integrated through the semiconductor substrate 10 may be bonded to each other.

As illustrated in FIG. 7B, subsequently, the semiconductor substrate 10 is removed from a back surface of the foundation insulating layer 11 by a method such as wet etching, polishing or the like.

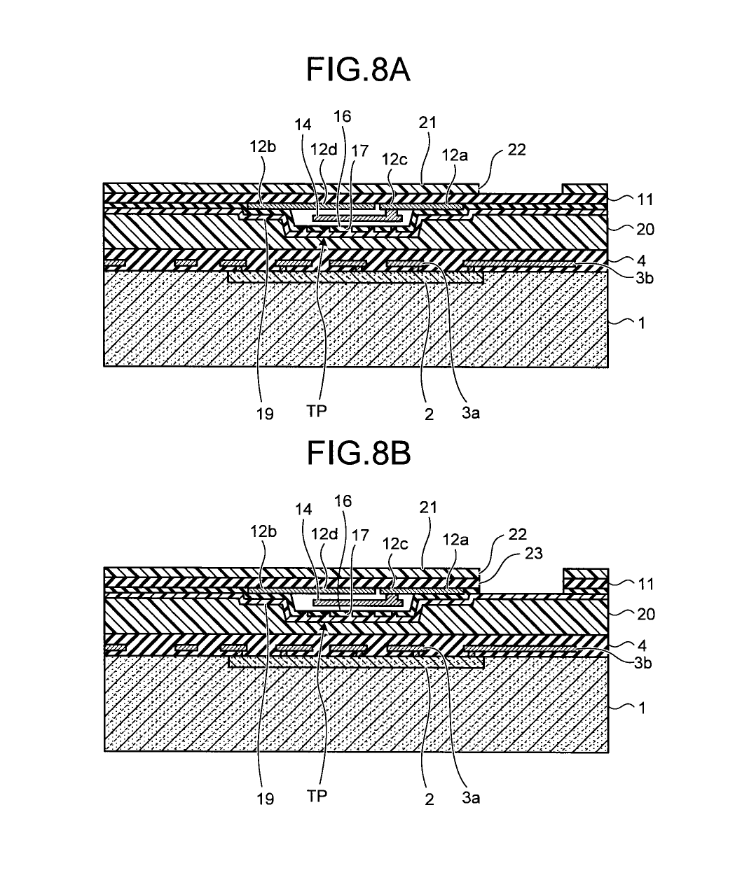

As illustrated in FIG. 8A, then, a reinforced layer 21 is formed on the back surface of the foundation insulating layer 11. Thereafter, the reinforced layer 21 is subjected to patterning to form, on the reinforced layer 21, an opening portion 22 for exposing the foundation insulating layer 11 provided on the pad electrode 3b.

As illustrated in FIG. 8B, next, the foundation insulating layer 11 and the cap layer 16 are subjected to etching through the opening portion 22 to form, on the foundation insulating layer 11 and the cap layer 16, an opening portion 23 for exposing the sealing layer 19 provided on the pad electrode 3b.

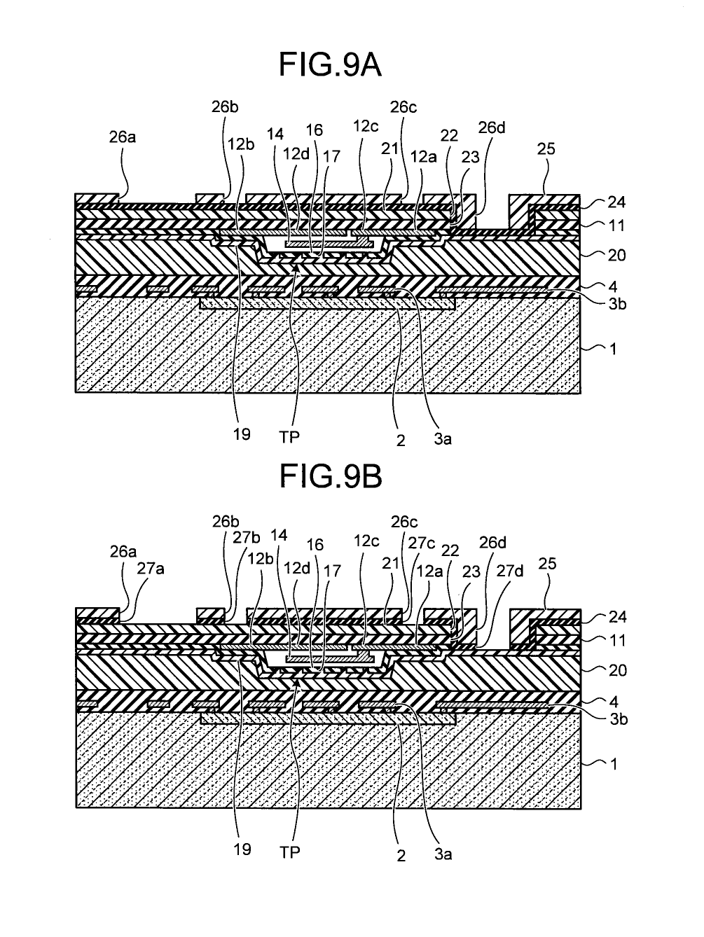

As illustrated in FIG. 9A, subsequently, a hard mask layer 24 is formed on the reinforced layer 21 by a method such as CVD. As a material of the hard mask layer 24, for example, it is possible to use an inorganic insulating film such as a silicon oxide film or a silicon nitride film.

Then, a resist layer 25 is formed on the hard mask layer 24 by a method such as spin coating. Thereafter, opening portions 26a to 26d are formed on the resist layer 25 by the photolithography technique. The opening portion 26a can be disposed adjacently to the opening portion 26b around the hollow body constituted by the cap layer 16. The opening portion 26b can be disposed on the internal electrode 12b. The opening portion 26c can be disposed on the internal electrode 12a. The opening portion 26d can be disposed on the pad electrode 3b.

As illustrated in FIG. 9B, next, the hard mask layer 24 is subjected to the etching by using, as a mask, the resist layer 25 on which the opening portions 26a to 26d are formed. Consequently, opening portions 27a to 27d are formed on the hard mask layer 24.

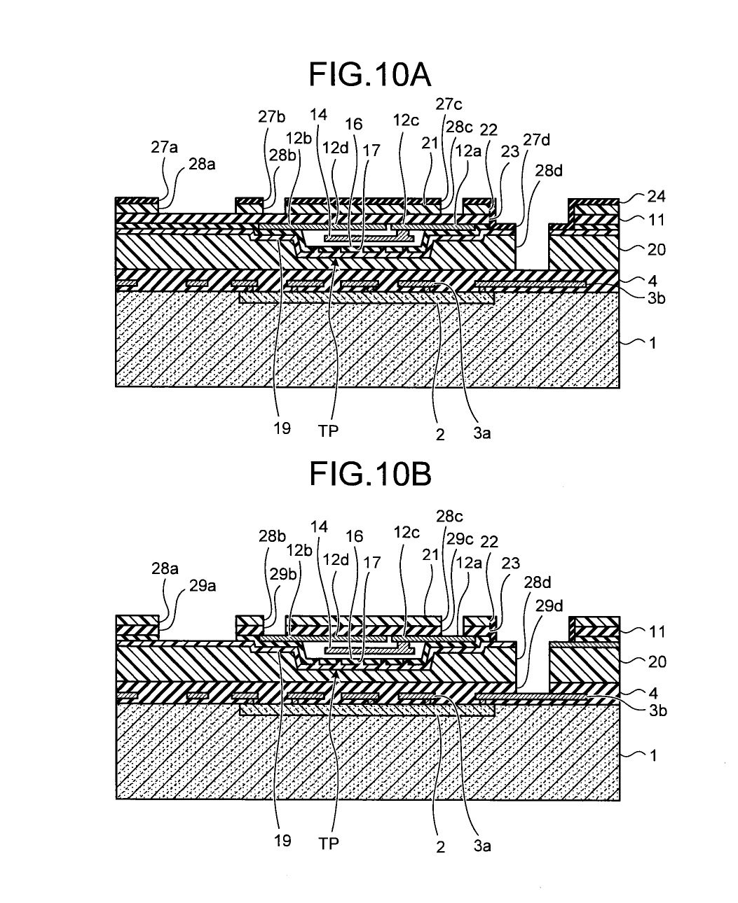

As illustrated in FIG. 10A, then, the resist layer 25 is removed from the hard mask layer 24. Thereafter, the sealing layer 19, the resin layer 20 and the reinforced layer 21 are subjected to the etching by using, as a mask, the hard mask layer 24 on which the opening portions 27a to 27d are formed. Consequently, openings 28a to 28c are formed on the reinforced layer 21, and furthermore, an opening portion 28d is formed on the sealing layer 19 and the resin layer 20.

As illustrated in FIG. 10B, next, the hard mask layer 24 is removed from the reinforced layer 21. Subsequently, the protective film 4, the foundation insulating layer 11 and the cap layer 16 are subjected to the etching by using, as a mask, the reinforced layer 21 on which the opening portions 28a to 28c are formed and the sealing layer 19 and the resin layer 20 on which the opening portion 28d is formed. Consequently, an opening portion 29a is formed on the foundation insulating layer 11 and the cap layer 16, opening portions 29b and 29c are formed on the foundation insulating layer 11, and an opening portion 29d is formed on the protective film 4.

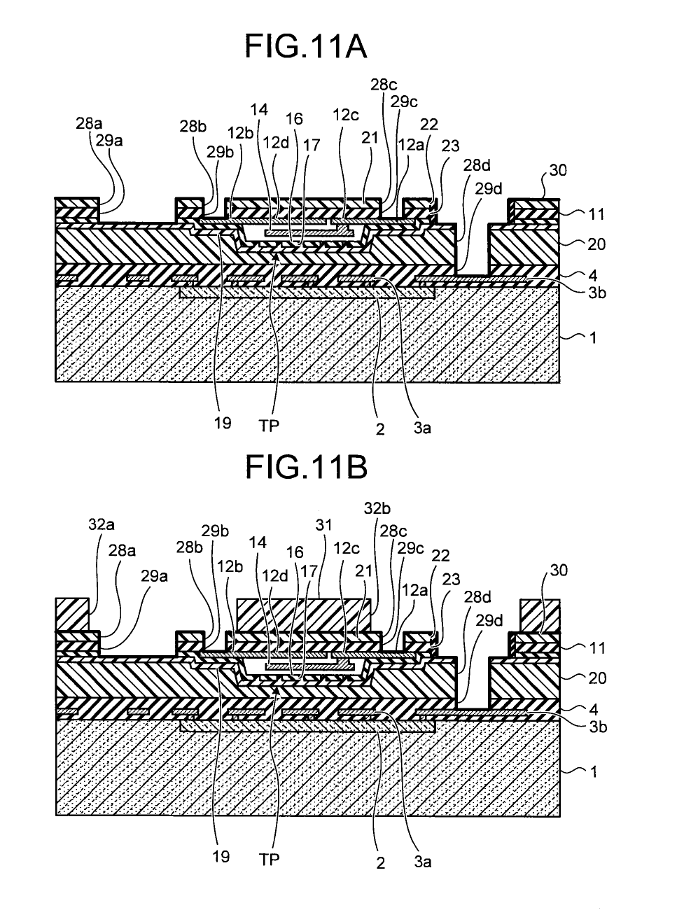

As illustrated in FIG. 11A, then, a seed metal layer 30 is formed on the reinforced layer 21 in such a manner that internal surfaces of the opening portions 29a to 29d are covered by a method such as sputtering or vapor deposition.

As illustrated in FIG. 11B, thereafter, a resist layer 31 is formed on the seed metal layer 30 by a method such as spin coating. Next, opening portions 32a and 32b are formed on the resist layer 31 by the photolithography technique. The opening portions 29a and 29b can be disposed on an inside of the opening portion 32a. The opening portions 29c and 29d can be disposed on an inside of the opening portion 32b.

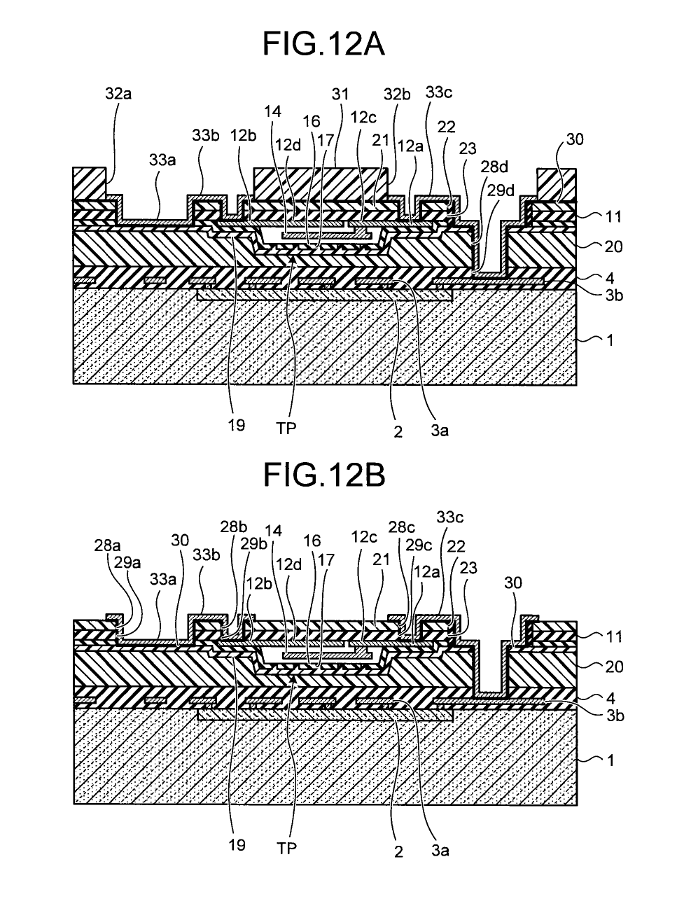

As illustrated in FIG. 12A, subsequently, a land electrode 33a and conductive layers 33b and 33c are formed on the seed metal layer 30 through the opening portions 32a and 32b by using a method such as plating.

As illustrated in FIG. 12B, then, the resist layer 31 is removed from the seed metal layer 30 by a method such as oxygen ashing. Thereafter, the seed metal layer 30 is subjected to the etching by using the land electrode 33a and the conductive layers 33b and 33c as a mask. Consequently, the seed metal layer 30 exposed from the land electrode 33a and the conductive layers 33b and 33c is removed from the reinforced layer 21.

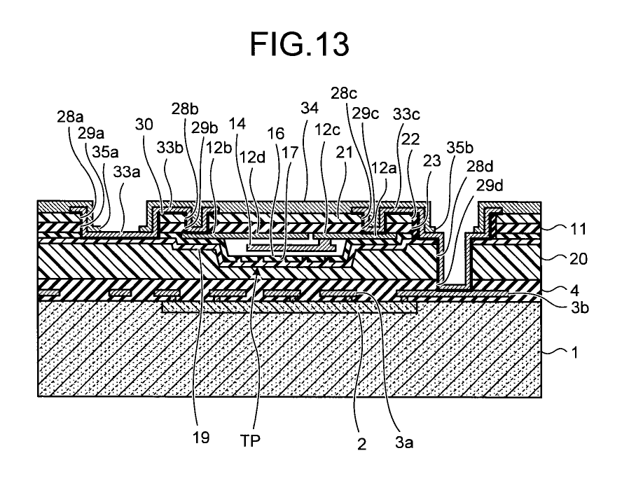

As illustrated in FIG. 13, next, a solder resist layer 34 is formed on the land electrode 33a and the conductive layers 33b and 33c by a method such as spin coating. Subsequently, the solder resist layer 34 is subjected to the patterning to form opening portions 35a and 35b on the solder resist layer 34. The opening portion 35a can be disposed on the land electrode 33a. The opening portion 35b can be disposed on the pad electrode 3b.

As illustrated in FIG. 1, then, there are formed projecting electrodes 36a and 36b connected to the land electrode 33a and the conductive layer 33c through the opening portions 35a and 35b respectively.

### Third Embodiment

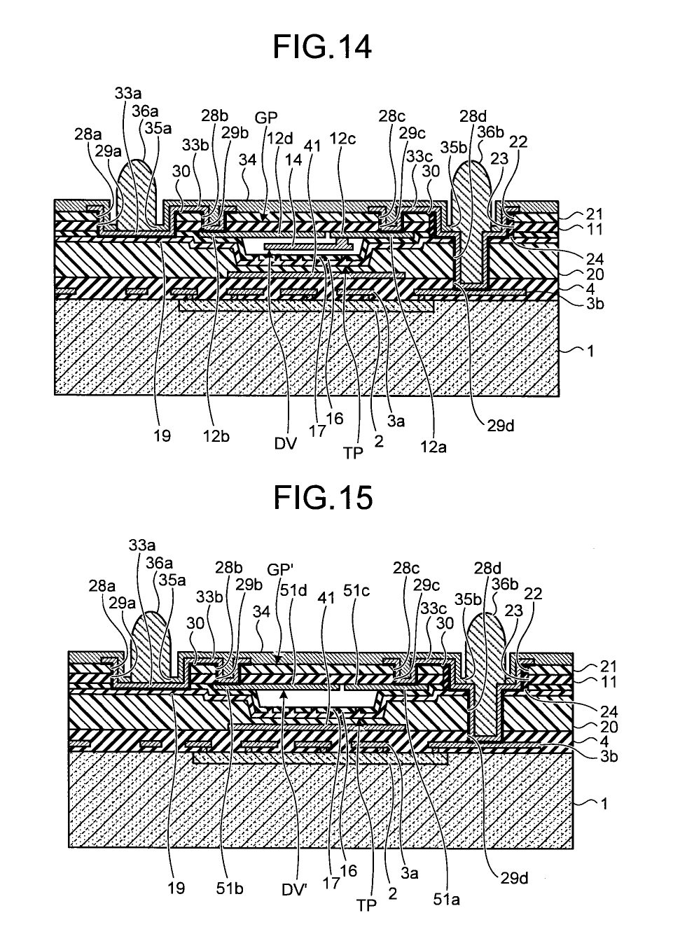

FIG. 14 is a sectional view illustrating a schematic structure of a stacked package according to a third embodiment.

In FIG. 14, the stacked package has an electromagnetic shielding layer 41 added to the structure of FIG. 1. The electromagnetic shielding layer 41 can be formed between a semiconductor element 2 and a hollow body constituted by a cap layer 16. As a material of the electromagnetic shielding layer 41, it is possible to use a metal such as Al or Cu.

A method of forming the electromagnetic shielding layer 41 can form a protective film 4 on a semiconductor substrate 1, can then form a metal layer on the protective film 4 through sputtering or the like, and can pattern the metal layer by using a photolithography technique and an etching technique. The electromagnetic shielding layer 41 may be embedded in the protective film 4. Alternatively, the protective film 4 may be formed on the semiconductor substrate 1 and a metal seal or the like may be then stuck onto the protective film 4.

The electromagnetic shielding layer 41 is formed between the semiconductor element 2 and the hollow body constituted by the cap layer 16. Consequently, it is possible to suppress the influence of a noise received from the semiconductor element 2 while preventing an increase in a parasitic capacitance between an electronic element DV and the electromagnetic shielding layer 41.

### Fourth Embodiment

FIG. 15 is a sectional view illustrating a schematic structure of a stacked package according to a fourth embodiment.

In FIG. 15, the stacked package is provided with a hollow chip GP′ in place of the hollow chip GP of the stacked package in FIG. 1. The hollow chip GP′ is provided with an electronic element DV′ in place of the electronic element DV in FIG. 1. The electronic element DV′ is provided with internal electrodes 51a and 51b and wirings 51c and 51d, and the internal electrodes 51a and 51b are connected to the wirings 51c and 51d, respectively. The wirings 51c and 51d can constitute a non-movable element such as an inductor.

A conductive layer 33b is connected to a back surface of the internal electrode 51a through a seed metal layer 30, and a conductive layer 33c is connected to a back surface of the internal electrode 51b through the seed metal layer 30.

Also in the case in which a non-movable element is disposed on a hollow body constituted by a cap layer 16, consequently, it is possible to provide an air gap between the electronic element DV′ and a semiconductor element 2. Thus, it is possible to reduce a parasitic capacitance between the electronic element DV′ and the semiconductor element 2.

Also in the fourth embodiment, the electromagnetic shielding layer 41 of FIG. 14 may be formed between the semiconductor element 2 and the hollow body constituted by the cap layer 16.

### Fifth Embodiment

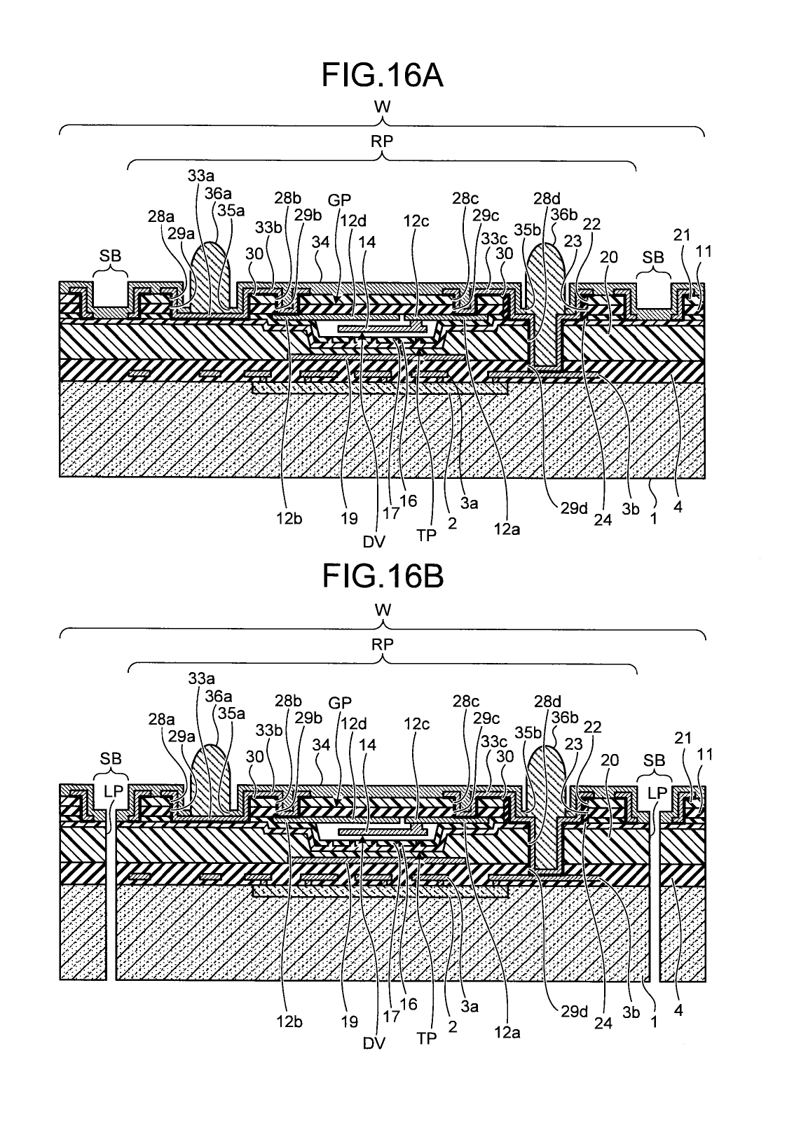

FIGS. 16A and 16B are sectional views illustrating a method of manufacturing a stacked package according to a fifth embodiment.

In FIG. 16A, a stacked wafer W is provided with a plurality of chip regions RP divided through a scribe line SB. The stacked package of FIG. 1 can be formed in each of the chip regions RP. A foundation insulating layer 11 and a cap layer 16 are removed from the scribe line SB. The foundation insulating layer 11 and the cap layer 16 in the scribe line SB may be removed in a lump at the step of FIG. 10B.

As illustrated in FIG. 16B, next, a cut groove LP is formed on the stacked wafer W along the scribe line SB so that the stacked wafer W is cut every chip region RP and is thus formed into individual pieces of stacked packages.

By removing the foundation insulating layer 11 and the cap layer 16 in the scribe line SB, it is possible to prevent the foundation insulating layer 11 and the cap layer 16 from being cracked in dicing, thereby enhancing a reliability also in the case in which the foundation insulating layer 11 and the cap layer 16 are constituted by inorganic insulating layers.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A stacked package comprising:
a semiconductor chip having a semiconductor element formed thereon;
a pad electrode formed on the semiconductor chip and connected to the semiconductor element;
a resin layer formed on the semiconductor chip;
a foundation insulating layer on which an electronic element and an internal electrode are formed;
a hollow body formed on the foundation insulating layer to cover the electronic element and having a top surface side embedded in the resin layer; and
a conductive layer formed on the foundation insulating layer and configured to connect the pad electrode and the internal electrode through a first opening portion for exposing a back surface of the internal electrode.

2. The stacked package according to claim 1, wherein the electronic element is an MEMS element.

3. The stacked package according to claim 1, further comprising an electromagnetic shielding layer formed between the semiconductor element and the hollow body.

4. The stacked package according to claim 1, wherein the resin layer covers the pad electrode.

5. The stacked package according to claim 4, further comprising a second opening portion formed on the resin layer and configured to expose the pad electrode.

6. The stacked package according to claim 5, further comprising a first projecting electrode connected to the pad electrode through the second opening portion.

7. The stacked package according to claim 1, wherein a side end of the resin layer is aligned with an outer periphery of the semiconductor chip.

8. The stacked package according to claim 1, wherein a side end of the foundation insulating layer is formed along an outer periphery of the semiconductor chip.

9. The stacked package according to claim 8, wherein the foundation insulating layer is removed along a scribe line of the semiconductor chip.

10. The stacked package according to claim 1, further comprising:
a cap layer provided between the resin layer and the hollow body and constituting an outer shell of the hollow body; and
a third opening portion provided on the cap layer and communicating with an inner part of the hollow body.

11. The stacked package according to claim 10, further comprising a sealing layer provided on the cap layer to close the third opening portion.

12. The stacked package according to claim 1, wherein the hollow body is embedded in the resin layer to keep away from the pad electrode.

13. The stacked package according to claim 1, further comprising a land electrode formed on the resin layer through a fourth opening portion formed on the foundation insulating layer and connected to the electronic element.

14. The stacked package according to claim 13, further comprising a second projecting electrode formed on the land electrode.

15. A stacked package comprising:
a semiconductor chip having a semiconductor element formed thereon;
a pad electrode formed on the semiconductor chip and connected to the semiconductor element;
a resin layer formed on the semiconductor chip to cover the pad electrode;
a foundation insulating layer having an electronic element formed thereon;
a hollow body formed on the foundation insulating layer to cover the electronic element and having a top surface side embedded in the resin layer; and
an electromagnetic shielding layer formed between the semiconductor element and the hollow body.

16. A stacked package comprising:
a semiconductor chip having a semiconductor element formed thereon;
a pad electrode formed on the semiconductor chip and connected to the semiconductor element;
a resin layer formed on the semiconductor chip to cover the pad electrode;
a foundation insulating layer having an electronic element formed thereon and disposed on the resin layer in such a manner that a side end is provided along an outer periphery of the semiconductor chip; and
a hollow body formed on the foundation insulating layer to cover the electronic element and having a top surface side embedded in the resin layer.

17. A method of manufacturing a stacked package comprising the steps of:
forming a resin layer on a semiconductor chip on which a pad electrode and a semiconductor element are formed; and
embedding a top surface side of a hollow body in the resin layer, the hollow body being formed on a foundation insulating layer to cover an electronic element.

18. The method of manufacturing a stacked package according to claim 17, wherein the electronic element is an MEMS element.

19. The method of manufacturing a stacked package according to claim 17, further comprising the steps of:
removing the foundation insulating layer along a scribe line of the semiconductor chip; and
embedding the hollow body in the resin layer and then cutting the semiconductor chip out along the scribe line.

20. The method of manufacturing a stacked package according to claim 17, further comprising the step of forming, on the resin layer, an opening portion configured to expose the pad electrode.
